(19) United States
(12) Patent Application Publication
(10) Pub. No.: US 2018/0069033 A1
(43) Pub. Date: Mar. 8, 2018

(54) TFT ARRAY SUBSTRATE STRUCTURE AND MANUFACTURING METHOD THEREOF

(71) Applicant: Wuhan China Star Optoelectronics Technology Co., Ltd., Wuhan City (CN)

(72) Inventor: Chen Chen, Wuhan City (CN)

(21) Appl. No.: 15/115,912

(22) PCT Filed: Jun. 17, 2016
(86) PCT No.: PCT/CN2016/086129

§ 371 Date: Aug. 2, 2016

(30) Foreign Application Priority Data
Jan. 21, 2016 (CN) 201610040034.2

(51) Int. Cl. H01L 27/12; G02F 1/1368; G02F 1/1362

(52) U.S. Cl. CPC H01L 27/1262; G02F 1/136227; G02F 1/1368; H01L 27/1218

(57) ABSTRACT

The present invention provides a TFT array substrate structure and a manufacturing method thereof, in which an interlayer dielectric layer (3) having a three-layer structure comprising a lower silicon nitride layer (31), a silicon oxide layer (32), and an upper silicon nitride layer (33) is used, wherein the lower silicon nitride layer (31) contains hydrogen for supplying hydrogen ions for hydrogenation operations and the upper silicon nitride layer (33) improves an isolation and protection capability of the interlayer dielectric layer (3) against impurity ions, so as to, when compared to the prior art that involves an intermediate dielectric layer having a dual-layer structure comprising only a silicon oxide layer and a silicon nitride layer, improve the isolation and protection capability of the interlayer dielectric layer against impurity ions, without affecting an effect of hydrogenation, and eliminating potential risk of contamination by impurity ions, shortening hydrogenation time, and increasing throughput.

### BACKGROUND OF THE INVENTION

### 1. Field of the Invention

The present invention relates to the field of display technology, and in particular to a thin-film transistor (TFT) array substrate structure and a manufacturing method thereof.

### 2. The Related Arts

Liquid crystal displays (LCDs) have a variety of advantages, such as thin device body, low power consumption, and being free of radiation, and thus have wide applications, such as liquid crystal televisions, mobile phones, personal digital assistants (PDAs), digital cameras, computer monitors, and notebook computer screens, so as to take a leading position in the field of flat panel displays.

Most of the LCDs that are currently available in the market are backlighting LCDs, which comprise a liquid crystal display panel and a backlight module. The working principle of the liquid crystal display panel is that liquid crystal molecules are filled between a thin-film transistor (TFT) array substrate and a color filter (CF) substrate and a drive voltage is applied to the two substrates to control a rotation direction of the liquid crystal molecules in order to refract out light emitting from the backlight module to generate an image.

The TFT array substrate is a circuit substrate that functions to drive the liquid crystal layer and comprises multiple gate lines and data lines such that the multiple gate lines and the multiple data lines collectively define multiple pixel units. Each of the pixel units comprises a thin-film transistor, a pixel electrode and a storage capacitor. The thin-film transistor comprises a gate electrode connected to the gate lines, a source electrode connected to the data lines, and a drain electrode connected to the pixel electrode. When the gate lines are driven, the thin-film transistor is in a conducting condition, allowing a grayscale voltage signal to be fed therein from a corresponding data line for loading the pixel electrode so as to make the pixel electrode induce a corresponding electrical field. Liquid crystal molecules contained in the liquid crystal layer are acted upon by the electrical field to change directions thereof thereby realizing displaying different images.

In the TFT array substrate, the gate electrode of the TFT and the gate line are located on the same layer and collectively constitute a first metal layer; and the source electrode and the drain electrode of the TFT and the data line are located on the same layer and collectively constitute a second metal layer, where an interlayer dielectric (ILD) layer is necessarily formed between the first metal layer and the second metal layer to serve as an insulation layer that isolates the first metal layer and the second metal layer from each other. Heretofore, the ILD layer is generally formed of a silicon oxide (SiOx) layer and a silicon nitride (SiNx) layer, wherein the silicon oxide layer provides excellent temperature keeping property and in-film stress, while the silicon nitride provides high hydrogen content and an excellent effect of isolating impurity ions. The processing sequences in forming an ILD layer adopted by the major manufacturers can be either the silicon oxide being formed first or the silicon nitride being formed first. Further, considering the factor that the silicon nitride layer possessing a high hydrogen content, which may generate a large amount of H⁺ in a high temperature to serve as a supply of hydrogen ions in a hydrogenation operation, as well the influence thereof on the yield rate, as shown in FIG. 1, all the major manufacturers prefers a film forming sequence that first forms a silicon nitride layer 20 (that comprises hydrogen) on a base plate 10 and then forms a silicon oxide layer 30 on the silicon nitride layer. Although such a structure of arranging the silicon oxide layer 30 atop the silicon nitride layer 20 ensures the process efficiency and yield rate of the hydrogenation process, using such a structure would need to take a potential risk of contamination caused by impurity ions due to the relatively poor effect of isolating impurity ions provided by the silicon oxide layer 30.

### SUMMARY OF THE INVENTION

An object of the present invention is to provide a thin-film transistor (TFT) array substrate structure, which, without causing an effect of hydrogenation, helps improve isolation and protection capability of an interlayer dielectric layer against impurity ions, eliminating potential risk of contamination by impurity ions, shortening hydrogenation time, and increasing throughput.

Another object of the present invention is to provide a manufacturing method of a TFT array substrate structure, which improves isolation and protection capability of an interlayer dielectric layer against impurity ions, eliminating potential risk of contamination by impurity ions, shortening hydrogenation time, and increasing throughput.

To achieve the above objects, the present invention provides a TFT array substrate structure, which comprises: a base plate, a first metal layer arranged on the base plate, an interlayer dielectric layer set on and covering the first metal layer, and a second metal layer arranged on the interlayer dielectric layer;

wherein the interlayer dielectric layer comprises a lower silicon nitride layer arranged on the first metal layer, a silicon oxide layer arranged on lower silicon nitride layer, and an upper silicon nitride layer arranged on the silicon oxide layer; and the lower silicon nitride layer contains hydrogen.

The TFT array substrate structure further comprises a first insulation layer arranged on an underside of the first metal layer, a semiconductor layer arranged on an underside of the first insulation layer, a buffer layer arranged on an underside of the semiconductor layer, and a light shielding layer arranged on an underside of the buffer layer; and

a planarization layer arranged on the second metal layer, a bottom electrode arranged on the planarization layer, a protective layer arranged on the bottom electrode, and a top electrode arranged on the protective layer.

The first metal layer comprises a gate electrode of the TFT and a gate line connected to the gate electrode of the TFT.

The second metal layer comprises a source electrode of a TFT, a drain electrode of the TFT, and a data line connected to the source electrode of the TFT.

The present invention also provides a manufacturing method of a TFT array substrate, which comprises the following steps:

(1) providing a base plate and depositing and patterning a first metal layer on the base plate;

(2) forming a film of a lower silicon nitride layer on the first metal layer, wherein the lower silicon nitride layer contains hydrogen;

(3) forming a film of a silicon oxide layer on the lower silicon nitride layer;

(4) forming a film of an upper silicon nitride layer on the silicon oxide layer, wherein the lower silicon nitride layer, the silicon oxide layer, and the upper silicon nitride layer collectively form an interlayer dielectric layer; and

(5) depositing and patterning a second metal layer on the interlayer dielectric layer.

Step (2) applies a chemical vapor deposition (CVD) process to form the film of the lower silicon nitride layer; step (3) applies a CVD process to form the film of the silicon oxide layer; and step (4) applies a CVD process to form the film of the upper silicon nitride layer.

Before step (1), a light shielding layer, a buffer layer, a semiconductor layer, and a first insulation layer are formed, in sequence from bottom to top, on the base plate.

After step (5), a planarization layer, a bottom electrode, a protective layer, and a top electrode are formed, in sequence from bottom to top, on the second metal layer.

The first metal layer comprises a gate electrode of a TFT and a gate line connected to the gate electrode of the TFT; and the second metal layer comprises a source electrode of the TFT, a drain electrode of the TFT, and a data line connected to the source electrode of the TFT.

The present invention further provides a TFT array substrate structure, which comprises: a base plate, a first metal layer arranged on the base plate, an interlayer dielectric layer set on and covering the first metal layer, and a second metal layer arranged on the interlayer dielectric layer;

wherein the interlayer dielectric layer comprises a lower silicon nitride layer arranged on the first metal layer, a silicon oxide layer arranged on lower silicon nitride layer, and an upper silicon nitride layer arranged on the silicon oxide layer; and the lower silicon nitride layer contains hydrogen;

wherein the first metal layer comprises a gate electrode of the TFT and a gate line connected to the gate electrode of the TFT; and

wherein the second metal layer comprises a source electrode of a TFT, a drain electrode of the TFT, and a data line connected to the source electrode of the TFT.

The efficacy of the present invention is that the present invention provides a TFT array substrate structure and a manufacturing method thereof, in which an interlayer dielectric layer having a three-layer structure comprising a lower silicon nitride layer, a silicon oxide layer, and an upper silicon nitride layer is used, wherein the lower silicon nitride layer contains hydrogen for supplying hydrogen ions for hydrogenation operations and the upper silicon nitride layer improves an isolation and protection capability of the interlayer dielectric layer against impurity ions, so as to, when compared to the prior art that involves an intermediate dielectric layer having a dual-layer structure comprising only a silicon oxide layer and a silicon nitride layer, improve the isolation and protection capability of the interlayer dielectric layer against impurity ions, without affecting an effect of hydrogenation, and eliminating potential risk of contamination by impurity ions, shortening hydrogenation time, and increasing throughput.

### BRIEF DESCRIPTION OF THE DRAWINGS

The features and technical contents of the present invention will be better understood by referring to the following detailed description and drawings the present invention. However, the drawings are provided for the purpose of reference and illustration and are not intended to limit the scope of the present invention. In the drawing:

FIG. 1 is a schematic view illustrating the structure of a conventional interlayer dielectric layer;

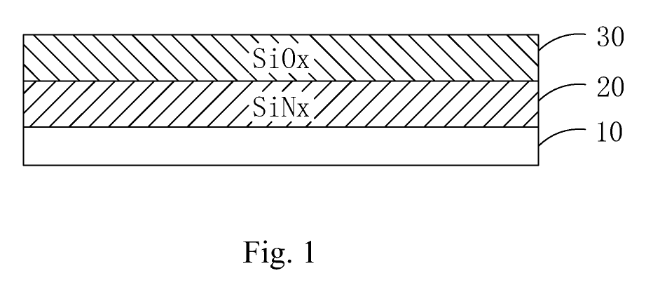

FIG. 2 is a schematic view illustrating a TFT array substrate structure according to the present invention; and

FIG. 3 is a flow chart illustrating a manufacturing method of a TFT array substrate structure according to the present invention.

### DETAILED DESCRIPTION OF THE PREFERRED EMBODIMENTS

To further expound the technical solution adopted in the present invention and the advantages thereof, a detailed description is given to a preferred embodiment of the present invention with reference to the attached drawings.

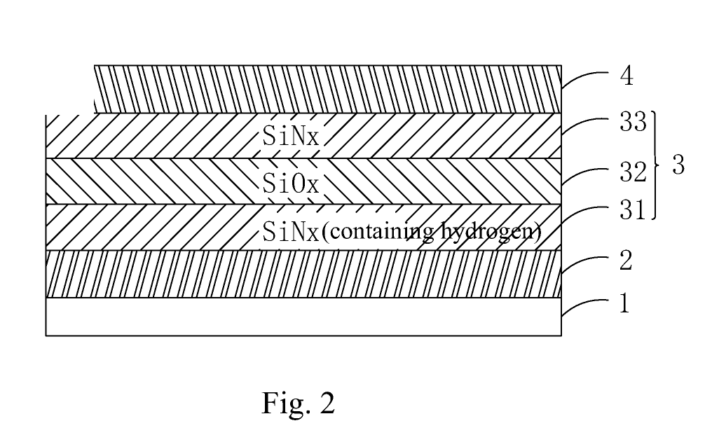

Referring to FIG. 2, firstly, the present invention provides a thin-film transistor (TFT) array substrate structure, which comprises: a base plate 1, a first metal layer 2 arranged on the base plate 1, an interlayer dielectric layer 3 set on and covering the first metal layer 2, and a second metal layer 4 arranged on the interlayer dielectric layer 3. The interlayer dielectric layer 3 comprises a lower silicon nitride layer 31 arranged on the first metal layer 2, a silicon oxide layer 32 arranged on the lower silicon nitride layer 31, and an upper silicon nitride layer 33 arranged on the silicon oxide layer 32. The lower silicon nitride layer 31 contains therein hydrogen.

Thee present invention uses a three-layer structure, which comprises the lower silicon nitride layer 31, the silicon oxide layer 32, and the upper silicon nitride layer 33, to form the interlayer dielectric layer 3, wherein the lower silicon nitride layer 31 contains hydrogen that serves as a supply of hydrogen ions in a hydrogenation process, whereby compared to the prior art where a dual-layer structure, which comprises a silicon nitride layer arranged on a silicon oxide layer, to form an interlayer dielectric layer, hydrogenation time can be relatively shortened and throughput can be increased. The upper silicon nitride layer 33 provides a more powerful capability of isolation and protection against impurity ions and thus, compared to the prior art dual-layer interlayer dielectric layer structure that comprises a silicon oxide layer arranged on a silicon nitride layer, it is possible to more effectively eliminate the potential risk of contamination by impurity ions.

Specifically, the array substrate further comprises, on an underside of the first metal layer 2, a first insulation layer arranged on the underside of the first metal layer 2, a semiconductor layer arranged on an underside of the first insulation layer, a buffer layer arranged on an underside of the semiconductor layer, and a light shielding layer arranged on an underside of the buffer layer; and a planarization layer arranged on the second metal layer 4, a bottom electrode arranged on the planarization layer, a protective layer arranged on the bottom electrode, and a top electrode arranged on the protective layer, this being of no difference from a conventional TFT array substrate structure so that no further detail will be provided herein. Preferably, the base plate 1 comprises a glass plate; the first metal layer 2 and the second metal layer 4 are formed of a material comprising one of molybdenum (Mo), titanium (Ti), aluminum (Al), and copper (Cu), or a stacked combination of multiple ones thereof; the top electrode and the bottom electrode are formed of a material comprising indium tin oxide (ITO).

Specifically, the first metal layer 2 comprises a gate electrode of a TFT and a gate line connected to the gate electrode of the TFT. The second metal layer 4 comprises a source electrode of the TFT, a drain electrode of the TFT, and a data line connected to the source electrode of the TFT.

Further, the semiconductor layer comprises a channel zone located at a middle area thereof and contact zones respectively located at two ends of the channel zone. The source and drain electrodes of the TFT are respectively connected, through vias formed in and extending through the interlayer dielectric layer 3 and the first insulation layer, to the contact zones at the two ends of the semiconductor layer. The top electrode is connected, through a via extending through the protective layer, the bottom electrode, and the planarization layer, to the drain electrode of the TFT.

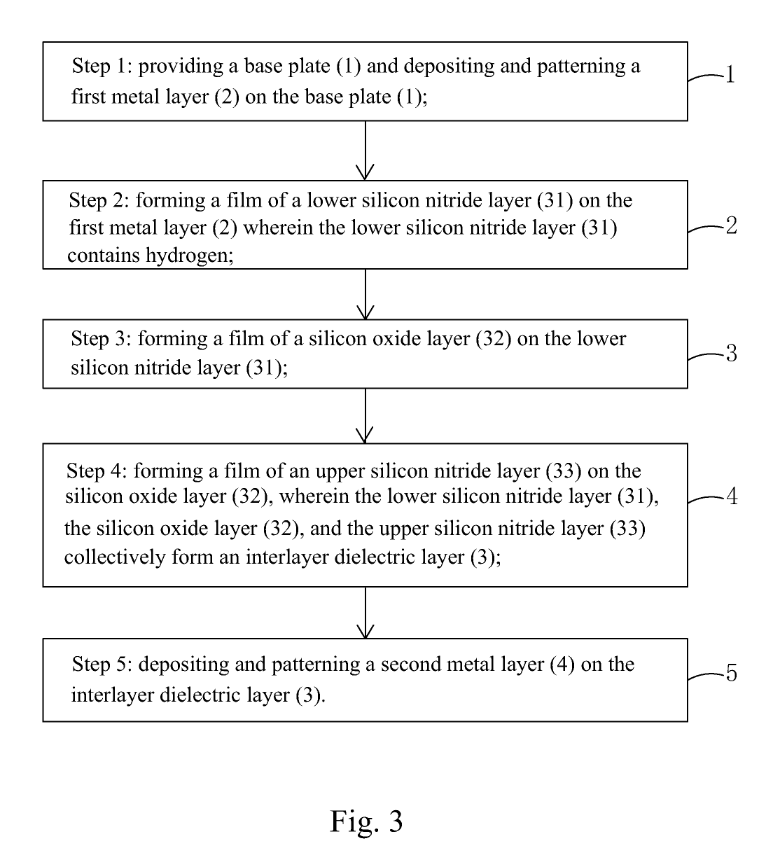

Referring to FIG. 3, in combination with FIG. 2, the present invention also provides a manufacturing method of an array substrate, comprising the following steps:

Step 1: providing a base plate 1 and depositing and patterning a first metal layer 2 on the base plate 1.

Specifically, the base plate 1 comprises, formed thereon in advance in sequence from bottom to top, a light shielding layer, a buffer layer, a semiconductor layer, and a first insulation layer.

The base plate 1 comprises a glass plate; and the first metal layer 2 is formed of a material comprising one of molybdenum, titanium, aluminum, and copper or a stacked combination of multiple ones thereof.

The semiconductor layer comprises a channel zone located at a middle area thereof and contact zones located at tow ends of the channel zone respectively. The first metal layer 2 comprises: a gate electrode of a TFT, and a gate line connected to the gate electrode of the TFT.

Step 2: applying a chemical vapor deposition (CVD) process to form a film of a lower silicon nitride layer 31 on the first metal layer 2 wherein the lower silicon nitride layer 31 contains hydrogen.

Step 3: applying a CVD process to form a film of a silicon oxide layer 32 on the lower silicon nitride layer 31.

Step 4: applying a CVD process to form a film of an upper silicon nitride layer 33 on the silicon oxide layer 32, wherein the lower silicon nitride layer 31, the silicon oxide layer 32, and the upper silicon nitride layer 33 collectively form an interlayer dielectric layer 3.

Step 5: depositing and patterning a second metal layer 4 on the interlayer dielectric layer 3.

Specifically, the second metal layer 4 comprises: a source electrode of the TFT, a drain electrode of the TFT, and a data line connected to the source electrode of the TFT.

Afterwards, a planarization layer, a bottom electrode, a protective layer, and a top electrode are formed, in sequence from bottom to top, on the second metal layer 4. The source and drain electrodes of the TFT are connected, through vias formed in and extending through the interlayer dielectric layer 3 and the first insulation layer, to the contact zones at the two ends of the semiconductor layer. The top electrode is connected, through a via extending through the protective layer, the bottom electrode, and the planarization layer, to the drain electrode of the TFT.

The present invention provides a manufacturing method of a TFT array substrate, wherein CVD processes are successively applied to form films of a lower silicon nitride layer 31, a silicon oxide layer 32, and an upper silicon nitride layer 33 so as to form an interlayer dielectric layer 3 having a three-layer structure comprising the lower silicon nitride layer 31, the silicon oxide layer 32, and the upper silicon nitride layer 33. The lower silicon nitride layer 31 contains hydrogen that serve as a supply of hydrogen ions in a hydrogenation process whereby compared to the prior art where a dual-layer structure, which comprises a silicon nitride layer arranged on a silicon oxide layer, to form an interlayer dielectric layer, hydrogenation time can be relatively shortened and throughput can be increased. The upper silicon nitride layer 33 provides a more powerful capability of isolation and protection against impurity ions and thus, compared to the prior art dual-layer interlayer dielectric layer structure that comprises a silicon oxide layer arranged on a silicon nitride layer, it is possible to more effectively eliminate the potential risk of contamination by impurity ions.

In summary, the present invention provides a TFT array substrate structure and a manufacturing method thereof, in which an interlayer dielectric layer having a three-layer structure comprising a lower silicon nitride layer, a silicon oxide layer, and an upper silicon nitride layer is used, wherein the lower silicon nitride layer contains hydrogen for supplying hydrogen ions for hydrogenation operations and the upper silicon nitride layer improves an isolation and protection capability of the interlayer dielectric layer against impurity ions, so as to, when compared to the prior art that involves an intermediate dielectric layer having a dual-layer structure comprising only a silicon oxide layer and a silicon nitride layer, improve the isolation and protection capability of the interlayer dielectric layer against impurity ions, without affecting an effect of hydrogenation, and eliminating potential risk of contamination by impurity ions, shortening hydrogenation time, and increasing throughput.

Based on the description given above, those having ordinary skills of the art may easily contemplate various changes and modifications of the technical solution and technical ideas of the present invention and all these changes and modifications are considered within the protection scope of right for the present invention as defined in the appended claims.

What is claimed is:

1. A thin-film transistor (TFT) array substrate structure, comprising: a base plate, a first metal layer arranged on the base plate, an interlayer dielectric layer set on and covering the first metal layer, and a second metal layer arranged on the interlayer dielectric layer;
wherein the interlayer dielectric layer comprises a lower silicon nitride layer arranged on the first metal layer, a silicon oxide layer arranged on lower silicon nitride layer, and an upper silicon nitride layer arranged on the silicon oxide layer; and the lower silicon nitride layer contains hydrogen.

2. The TFT array substrate structure as claimed in claim 1 further comprising a first insulation layer arranged on an underside of the first metal layer, a semiconductor layer arranged on an underside of the first insulation layer, a buffer layer arranged on an underside of the semiconductor layer, and a light shielding layer arranged on an underside of the buffer layer.

3. The TFT array substrate structure as claimed in claim 2 further comprising a planarization layer arranged on the second metal layer, a bottom electrode arranged on the planarization layer, a protective layer arranged on the bottom electrode, and a top electrode arranged on the protective layer.

4. The TFT array substrate structure as claimed in claim 1, wherein the first metal layer comprises a gate electrode of the TFT and a gate line connected to the gate electrode of the TFT.

5. The TFT array substrate structure as claimed in claim 1, wherein the second metal layer comprises a source electrode of a TFT, a drain electrode of the TFT, and a data line connected to the source electrode of the TFT.

6. A manufacturing method of a thin-film transistor (TFT) array substrate, comprising the following steps:
(1) providing a base plate and depositing and patterning a first metal layer on the base plate;
(2) forming a film of a lower silicon nitride layer on the first metal layer, wherein the lower silicon nitride layer contains hydrogen;
(3) forming a film of a silicon oxide layer on the lower silicon nitride layer;
(4) forming a film of an upper silicon nitride layer on the silicon oxide layer, wherein the lower silicon nitride layer, the silicon oxide layer, and the upper silicon nitride layer collectively form an interlayer dielectric layer; and
(5) depositing and patterning a second metal layer on the interlayer dielectric layer.

7. The manufacturing method of the TFT array substrate as claimed in claim 6, wherein step (2) applies a chemical vapor deposition (CVD) process to form the film of the lower silicon nitride layer; step (3) applies a CVD process to form the film of the silicon oxide layer; and step (4) applies a CVD process to form the film of the upper silicon nitride layer.

8. The manufacturing method of the TFT array substrate as claimed in claim 6, wherein before step (1), a light shielding layer, a buffer layer, a semiconductor layer, and a first insulation layer are formed, in sequence from bottom to top, on the base plate.

9. The manufacturing method of the TFT array substrate as claimed in claim 8, wherein after step (5), a planarization layer, a bottom electrode, a protective layer, and a top electrode are formed, in sequence from bottom to top, on the second metal layer.

10. The manufacturing method of the TFT array substrate as claimed in claim 6, wherein the first metal layer comprises a gate electrode of a TFT and a gate line connected to the gate electrode of the TFT; and the second metal layer comprises a source electrode of the TFT, a drain electrode of the TFT, and a data line connected to the source electrode of the TFT.

11. A thin-film transistor (TFT) array substrate structure, comprising: a base plate, a first metal layer arranged on the base plate, an interlayer dielectric layer set on and covering the first metal layer, and a second metal layer arranged on the interlayer dielectric layer;
wherein the interlayer dielectric layer comprises a lower silicon nitride layer arranged on the first metal layer, a silicon oxide layer arranged on lower silicon nitride layer, and an upper silicon nitride layer arranged on the silicon oxide layer; and the lower silicon nitride layer contains hydrogen;
wherein the first metal layer comprises a gate electrode of the TFT and a gate line connected to the gate electrode of the TFT; and
wherein the second metal layer comprises a source electrode of a TFT, a drain electrode of the TFT, and a data line connected to the source electrode of the TFT.

12. The TFT array substrate structure as claimed in claim 11 further comprising a first insulation layer arranged on an underside of the first metal layer, a semiconductor layer arranged on an underside of the first insulation layer, a buffer layer arranged on an underside of the semiconductor layer, and a light shielding layer arranged on an underside of the buffer layer.

13. The TFT array substrate structure as claimed in claim 12 further comprising a planarization layer arranged on the second metal layer, a bottom electrode arranged on the planarization layer, a protective layer arranged on the bottom electrode, and a top electrode arranged on the protective layer.
